(19) United States
(12) Patent Application Publication
(10) Pub. No.: US 2007/0029555 A1
(43) Pub. Date: Feb. 8, 2007

(54) Edge-emitting LED light source

(76) Inventors: Steven D. Lester, Palo Alto, CA (US); Virginia M. Robbins, Los Gatos, CA (US); Jeffrey N. Miller, Los Altos Hills, CA (US); Scott W. Corzine, Sunnyvale, CA (US)

Correspondence Address: AVAGO TECHNOLOGIES, LTD., P.O. BOX 1920, DENVER, CO, 80201-1920, US

(21) Appl. No.: 11/197,010

(22) Filed: Aug. 4, 2005

(51) Int. Cl. H01L 33/00

(52) U.S. Cl. 257/79

(57) ABSTRACT

Edge-emitting LED light source, and method for fabricating an edge-emitting LED light source. The edge-emitting LED light source has a plurality of edge-emitting LEDs arranged in close proximity to one another to define an array of edge-emitting LEDs. Light beams separately emitted by each of the plurality of edge-emitting LEDs in the array together form a single light beam that has a generally two-dimensional cross-sectional shape, for example, a square or other rectangular shape, and an increased overall light flux.

### DESCRIPTION OF RELATED ART

Conventional light-emitting diodes (LEDs) are not sufficiently bright (i.e. do not generate sufficient light/unit area/unit angle), and do not have sufficient light flux (time rate of flow of energy) to be used in many applications. An edge-emitting LED, on the other hand, can provide a relatively bright light source. For example, GaN (Gallium Nitride)-based edge-emitting LEDs such as edge-emitting LEDs based on AlGaInN or InGaN, can provide a very bright blue or green light beam.

Edge-emitting LEDs, however, are essentially line light sources in that they emit a light beam having a very narrow elongated cross-sectional shape; and, as a result, are also not suitable for use in many applications. For example, applications such as imaging onto a spatial light modulator or coupling into an optical fiber require a light source that emits a light beam having a more two-dimensional cross-sectional shape than can be provided by an edge-emitting LED.

### SUMMARY OF THE INVENTION

In accordance with the invention, an edge-emitting LED light source and a method for fabricating an edge-emitting LED light source are provided. The edge-emitting LED light source has a plurality of edge-emitting LEDs arranged in close proximity to one another to define an array of edge-emitting LEDs. Light beams separately emitted by each of the plurality of edge-emitting LEDs in the array together form a single light beam that has a generally two-dimensional cross-sectional shape, for example, a square or other rectangular shape, and an increased overall light flux. The edge-emitting LED light source can be effectively used for imaging onto a light modulator, for coupling into an optical fiber and for other applications requiring a light source.

### BRIEF DESCRIPTION OF THE DRAWINGS

Furthermore, the invention provides embodiments and other features and advantages in addition to or in lieu of those discussed above. Many of these features and advantages are apparent from the description below with reference to the following drawings.

FIG. 1 is a schematic plan view of an edge-emitting LED that is known in the art to assist in explaining embodiments in accordance with the invention;

FIG. 2 is a schematic side view of an edge-emitting LED light source according to an exemplary embodiment in accordance with the invention;

FIG. 3 is a schematic plan view of an edge-emitting LED light source according to a further exemplary embodiment in accordance with the invention;

FIG. 4 is a schematic plan view of an edge-emitting LED light source according to a further exemplary embodiment in accordance with the invention;

FIG. 5 is a schematic plan view of an edge-emitting LED light source according to a further exemplary embodiment in accordance with the invention; and

FIG. 6 is a flowchart that illustrates a method for fabricating an edge-emitting LED light source according to an exemplary embodiment in accordance with the invention.

### DETAILED DESCRIPTION OF THE EXEMPLARY EMBODIMENTS OF THE INVENTION

Exemplary embodiments in accordance with the invention provide an edge-emitting light-emitting diode (LED) light source and a method for fabricating an edge-emitting LED light source.

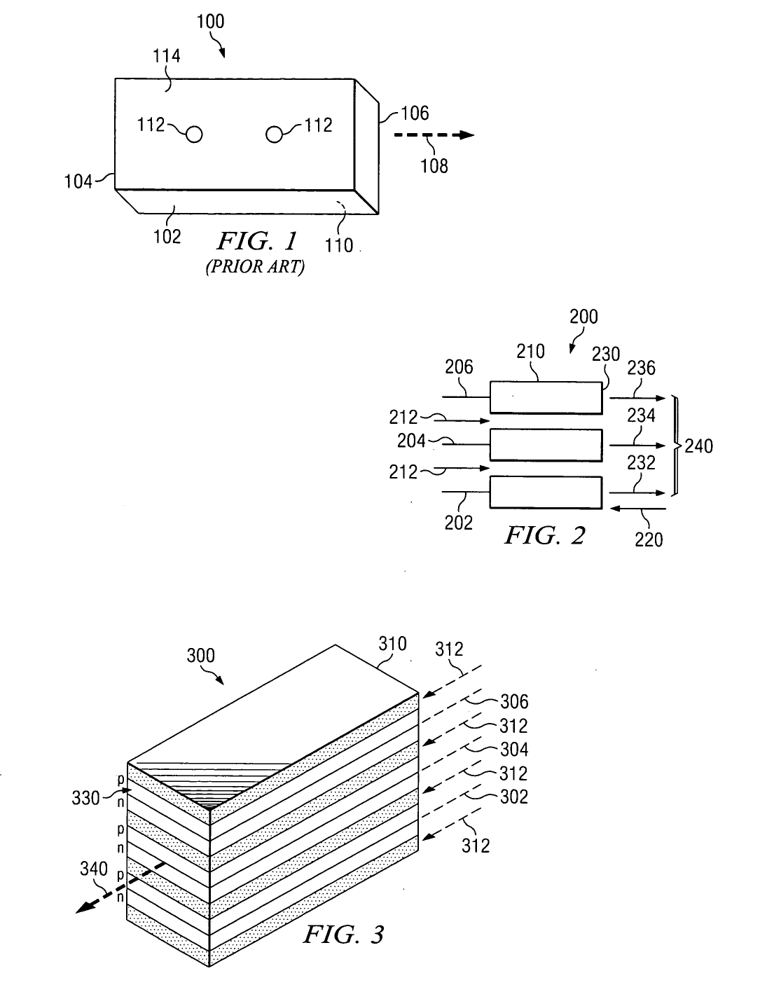

FIG. 1 is a schematic plan view of an edge-emitting LED that is known in the art to assist in explaining embodiments in accordance with the invention. The edge-emitting LED is generally designated by reference number 100, and comprises a GaN (Gallium Nitride)-based edge-emitting LED, specifically, an AlGaInN-based edge-emitting LED. GaN-based edge-emitting LEDs are preferable over conventional surface-emitting LEDs in many applications because they can provide a very bright blue or green light beam.

Edge-emitting LED 100 includes a sapphire (Al₂O₃) substrate 102 and GaN-based epitaxial layers 104. As is known to those skilled in the art, much of the light produced by LED 100 (˜70 percent of the light) is trapped between substrate 102 and epitaxial layers 104, and is guided to the edges of the LED. Reflectors (not shown in FIG. 1) are usually provided on non-light emitting edge 110 of LED 100 to redirect light guided to edge 110 to light-emitting edge 106 such that a bright blue or green light beam 108 is emitted from light-emitting edge 106.

Two contacts, schematically illustrated at 112, are typically provided on top surface 114 of epitaxial layers 104 to provide electrical connection for the LED.

GaN-based edge-emitting LED 100 emits a light beam having a very narrow elongated cross-sectional shape, for example, a beam that is about 500 microns wide and about 4 microns thick. As a result, edge-emitting LED 100 is essentially a line light source and is not suitable for use in applications that desire a light beam having a more two-dimensional cross-sectional shape, such as a square or other rectangular shape. Thus, although a GaN-based edge-emitting LED is a bright light source; its usefulness is severely restricted by the shape of the light beam it emits.

FIG. 2 is a schematic side view of an edge-emitting LED light source according to an exemplary embodiment in accordance with the invention. The light source is generally designated by reference number 200, and comprises a plurality of edge-emitting LEDs arranged in close proximity to one another to define an array of edge-emitting LEDs. In the exemplary embodiment in accordance with the invention illustrated in FIG. 2, light source 200 comprises three edge-emitting LEDs 202, 204 and 206 arranged one above the other to define an array 210 comprising a vertical stack of edge-emitting LEDs that are spaced from one another by narrow gaps 212. As will become apparent hereinafter, however, array 210 illustrated in FIG. 2 is intended to be exemplary only as edge-emitting LED light sources according to the invention can comprise any desired plurality of edge-emitting LEDs arranged in an array of any desired configuration.

According to an exemplary embodiment in accordance with the invention, edge-emitting LEDs 202, 204 and 206 comprise GaN-based edge-emitting LEDs, for example, AlGaInN-based edge-emitting LEDs such as illustrated in FIG. 1. GaN-based edge-emitting LEDs are desirable light sources in many applications because they emit a bright blue or green light beam. It should be understood, however, that the invention is not limited to an edge-emitting LED of any particular type or to an edge-emitting LED that emits light of any particular color.

Edge-emitting LEDs 202, 204 and 206 are preferably spaced from one another by a distance of from about 1 to about 50 microns. The spacing should be sufficient to enable each LED to be electrically connected to an external source via contacts thereon (e.g., contacts 112 illustrated in FIG. 1), but small enough such that the light beam emitted by light source 200 will be as bright as desired (in general, the closer LEDs 202, 204 and 206 are to one another, the brighter the light beam emitted by light source 200).

As shown in FIG. 2, edge-emitting LEDs 202, 204 and 206 emit separate light beams 232, 234 and 236, respectively, from light-emitting edge 230 of light source 200, each light beam having an elongated, narrow cross-sectional shape typical of an edge-emitting LED. The individual light beams are substantially parallel to one another and will diverge as they leave the LEDs. Because of the close proximity of LEDs 202, 204 and 206 to one another, the individual beams will blend together at a modest distance from the LEDs to define a single, uniform light beam 240 that has a generally two-dimensional cross-sectional shape, such as a square or other rectangular shape, and that has an increased overall light flux. As a result, edge-emitting LED light source 200 comprises a bright, substantially rectangular two-dimensional edge-emitting LED light source that can be effectively used in applications that require or desire a two-dimensional light source.

The plurality of closely spaced edge-emitting LEDs can be packaged together in various ways to provide light source 200. For example, a stack of LEDs such as illustrated in FIG. 2, or a two-dimensional array of LEDs, as will be described hereinafter, can be affixed to a heat sink. An array of LEDs can also be placed in a reflective cavity, or cup, in order to redirect any light that may be emitted by the LEDs in directions other than the desired direction.

FIG. 3 is a schematic plan view of an edge-emitting LED light source according to a further exemplary embodiment in accordance with the invention. The light source is generally designated by reference number 300, and similar to edge-emitting LED light source 200 illustrated in FIG. 2, includes three edge-emitting LEDs 302, 304 and 306 arranged one above the other to define an array 310 comprising a vertical stack of edge-emitting LEDs. Edge-emitting LED light source 300 differs from edge-emitting LED light source 200 in that instead of providing a narrow gap 212 between each edge-emitting LED as in light source 200, light source 300 includes a contact member 312 between each edge-emitting LED 302, 304 and 306 for electrically coupling the plurality of LEDs. In the exemplary embodiment in accordance with the invention illustrated in FIG. 3, contacts 312 comprise thin layers of silver, although contact members formed of other materials such as, for example, contact members having aluminum on one side and gold on the opposite side may also be used if desired.

Contact members 312 are positioned between each edge-emitting LED 302, 304 and 306 to effectively and compactly electrically couple the plurality of LEDs in series via contacts on the LEDs. (In the exemplary embodiment in accordance with the invention illustrated in FIG. 3, a single contact is provided on each side of the LEDs to make electrical contact with the silver layers.) In addition, silver contact members 312 are provided on the bottom surface of bottom LED 202 and on the top surface of top LED 206 to provide electrical connection to an external source. In a manner similar to edge-emitting LED light source 200, individual edge-emitting LEDs 302, 304 and 306 in edge-emitting LED light source 300 will emit separate, closely spaced light beams from light-emitting edge 330 of light source 300 that have a narrow elongated cross-sectional shape, but that blend together to form a single light beam 340 that has a generally two-dimensional cross-sectional shape, such as a square or other rectangular shape, and that has an increased overall light flux.

As illustrated in FIG. 3, forming contact members 312 of silver provides the advantage that the contact members can serve as a p-contact for some of the LEDs and as an n-contact for others of the LEDs. In addition, silver contact members provide the further advantages of being able to effectively remove heat from LED light source 300, and of being a good reflector so they will not absorb stray light from the light source. According to exemplary embodiments in accordance with the invention, silver contact members 312 have a thickness of from about 1μ to a few 10's of microns, for example, about 10-20μ. In general, the thinner the silver contact members, the closer LEDs 302, 304 and 306 will be to one another and the brighter the light beam that will be emitted by light source 300. On the other hand, thicker silver contact members will be able to remove more heat from the light source. Thus, thicker silver contact members are provided when increased heat removal is desired, and thinner contact members are provided when a brighter light source is desired.

Light source 300 can be fabricated by simply positioning LEDs 302, 304 and 306 one above the other with silver contact members between the LEDs and above and below the stack of LEDs. The stack of LEDs can be bonded together, for example, by melting the silver contact members onto the surfaces of the LEDs.

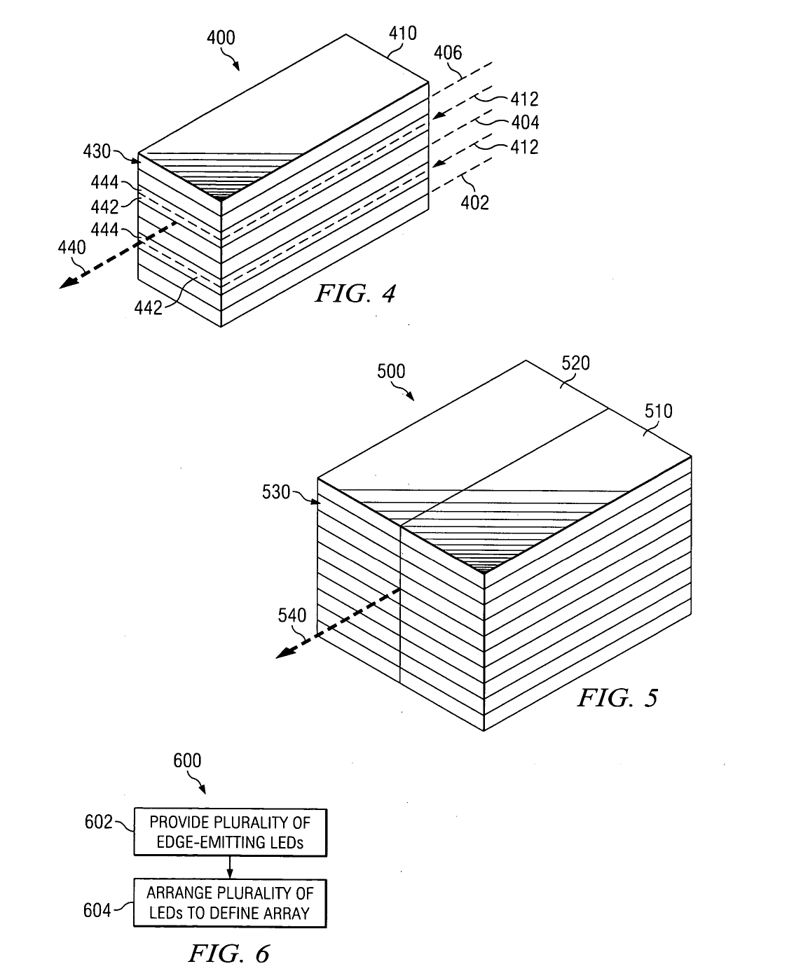

FIG. 4 is a schematic plan view of an edge-emitting LED light source according to a further exemplary embodiment in accordance with the invention. The edge-emitting LED light source is generally designated by reference number 400, and, similar to edge-emitting LED light source 300 in FIG. 3, includes an array 410 of edge-emitting LEDs 402, 404 and 406 arranged as a vertical stack of LEDs. Also similar to edge-emitting light source 300, individual edge-emitting LEDs 402, 404 and 406 will emit separate closely spaced light beams from light-emitting edge 430 of light source 400 that have a narrow elongated cross-sectional shape, but that blend together to define a single light beam 440 that has a generally two-dimensional cross-sectional shape, such as a square or other rectangular shape, and that has an increased overall light flux.

Edge-emitting LED light source 400 differs from edge-emitting LED light source 300 in that the plurality of silver contact members 312 in light source 300 are replaced by a plurality of tunnel junctions 412. Specifically, the plurality of edge-emitting LEDs are stacked in a series array using tunnel junctions 412 formed within the epitaxial layers of the LEDs.

In an exemplary embodiment in accordance with the invention wherein edge-emitting LEDs 402, 404 and 406 comprise GaN-based edge-emitting LEDs, tunnel junctions 412 each comprise p++AlGaInN layer 442 and n++AlGaInN layer 444. Layer 442 is heavily p doped, for example, with magnesium, to a concentration in the range from about 6·10¹⁹/cm³ to about 1·10²⁰/cm³. Layer 444 is heavily n doped, typically with silicon, to a concentration much greater than 1·10²⁰/cm³, for example, in the range of from about 2·10²⁰/cm³ to about 3·10²⁰/cm³.

In the exemplary embodiments illustrated in FIGS. 2-4, edge-emitting LED light sources 200-400 each comprises an array in the form of a vertical stack of individual edge-emitting LEDs. Such a stack will provide a light beam of generally rectangular-shaped cross-section having a width corresponding to the width of each LED and a height that is a function of the number of LEDs in the stack. For example, a light source composed of three closely-spaced edge-emitting LEDs will emit a light beam having a cross-sectional shape that is about 200-500 microns wide and about 0.1 microns high, and that will look like one continuous light source. In accordance with the invention, however, edge-emitting LED light sources can be fabricated to have a plurality of edge-emitting LEDs arranged in arrays having different configurations in order to provide a light beam having any desired two-dimensional cross-sectional shape.

FIG. 5 is a schematic plan view of an edge-emitting LED light source according to a further exemplary embodiment in accordance with the invention. The light source is generally designated by reference number 500 and comprises two stacks 510 and 520 of edge-emitting LEDs arranged one above the other, for example, one of stacks 210, 310 or 410 illustrated in FIGS. 2-4. Stacks 510 and 520 are positioned side-by-side in close proximity to one another to provide light beam 540 emitted from light-emitting edge 530 of light source 500 that has a height corresponding to the number of edge-emitting LEDs in the stacks and a width corresponding to the combined width of the two stacks of edge-emitting LEDs.

Edge-emitting LED light source 500 can be useful in applications that desire a light beam having substantially the same cross-sectional shape as a display such as a CRT screen or the like. In general, an edge-emitting LED light source according to the invention can be constructed to include any desired number of stacks of individual edge-emitting LEDs arranged side-by-side or in any other configuration. For example, edge-emitting LEDs can also be arranged as one or more horizontal rows if desired.

FIG. 6 is a flowchart that illustrates a method for fabricating an edge-emitting LED light source according to an exemplary embodiment in accordance with the invention. The method is generally designated by reference number 600 and begins by providing a plurality of edge-emitting LEDs (Step 602). The plurality of edge-emitting LEDs are then arranged in close proximity to one another to define an array of edge-emitting LEDs wherein light beams separately emitted by each of the plurality of edge-emitting LEDs in the array together form a single light beam that has a generally two-dimensional cross-sectional shape (Step 604).

While what has been described constitute exemplary embodiments in accordance with the invention, it should be recognized that the invention can be varied in numerous ways without departing from the scope thereof. Because exemplary embodiments in accordance with the invention can be varied in numerous ways, it should be understood that the invention should be limited only insofar as is required by the scope of the following claims.

We claim:

1. A light source, comprising:
a plurality of edge-emitting LEDs arranged in close proximity to one another to define an array of edge-emitting LEDs, wherein light beams separately emitted by each of the plurality of edge-emitting LEDs in the array together form a single light beam that has a generally two-dimensional cross-sectional shape.

2. The light source according to claim 1, wherein the plurality of edge-emitting LEDs are arranged to define at least one stack of edge-emitting LEDs.

3. The light source according to claim 2, wherein the at least one stack of edge-emitting LEDs comprises a plurality of stacks of edge-emitting LEDs arranged side-by-side.

4. The light source according to claim 2, and further including a gap between each edge-emitting LED in the at least one stack of edge-emitting LEDs.

5. The light source according to claim 4, wherein the gap has a width of from about 1 micron to about 50 microns.

6. The light source according to claim 2, and further including a contact member between each edge-emitting LED in the at least one stack of edge-emitting LEDs for electrically connecting the plurality of LEDs in the at least one stack in series.

7. The light source according to claim 6, wherein the contact member comprises a silver contact member.

8. The light source according to claim 7, wherein the silver contact member has a thickness of from about 1μ to about 20μ.

9. The light source according to claim 6, and further including a contact member on each of opposite sides of the at least one stack of edge-emitting LEDs for electrically connecting the light source to a power source.

10. The light source according to claim 2, and further including a tunnel junction between each edge-emitting LED in the at least one stack of edge-emitting LEDs.

11. The light source according to claim 1, wherein the plurality of edge-emitting LEDs comprise a plurality of GaN-based edge-emitting LEDs.

12. The light source according to claim 11, wherein the plurality of GaN-based edge-emitting LEDs comprise a plurality of at least one of AlGaInN and InGaN edge-emitting LEDs.

13. A method for fabricating an edge-emitting LED light source, comprising:
arranging a plurality of edge-emitting LEDs in close proximity to one another to define an array of edge-emitting LEDs, wherein light beams separately emitted by each of the plurality of edge-emitting LEDs in the array together form a single light beam that has a generally two-dimensional cross-sectional shape.

14. The method according to claim 13, wherein arranging a plurality of edge-emitting LEDs in close proximity to one another to define an array of edge-emitting LEDs comprises arranging the plurality of edge-emitting LEDs to define at least one stack of edge-emitting LEDs.

15. The method according to claim 14, wherein arranging the plurality of edge-emitting LEDs to define at least one stack of edge-emitting LEDs comprises:
arranging the plurality of edge-emitting LEDs to define a plurality of stacks of edge-emitting LEDs arranged side-by-side.

16. The method according to claim 14, and further comprising:
providing a gap between each edge-emitting LED in the at least one stack.

17. The method according to claim 14, and further comprising:
providing a contact member between each edge-emitting LED in the at least one stack for electrically connecting each edge-emitting LED in the at least one stack in series.

18. The method according to claim 17, wherein providing a contact member between each edge-emitting LED in the at least one stack for electrically connecting each edge-emitting LED in the at least one stack in series, comprises:
providing a silver contact member between each edge-emitting LED in the at least one stack for electrically connecting each edge-emitting LED in the at least one stack in series.

19. The method according to claim 17 and further comprising:
providing a contact member on each of opposite sides of the at least one stack of edge-emitting LEDs for electrically connecting the light source to a power source.

20. The method according to claim 14, and further comprising:
providing a tunnel junction between each edge-emitting LED in the at least one stack.
